(19) United States
(12) Patent Application Publication
(10) Pub. No.: US 2020/0239299 A1
(43) Pub. Date: Jul. 30, 2020

(54) PACKAGING STRUCTURES AND PACKAGING METHODS FOR ULTRASOUND-ON-CHIP DEVICES

(71) Applicant: Butterfly Network, Inc., Guilford, CT (US)

(72) Inventors: Jianwei Liu, Fremont, CA (US); Keith G. Fife, Palo Alto, CA (US)

(73) Assignee: Butterfly Network, Inc., Guilford, CT (US)

(21) Appl. No.: 16/774,956

(22) Filed: Jan. 28, 2020

Related U.S. Application Data
(60) Provisional application No. 62/798,446, filed on Jan. 29, 2019.

(51) Int. Cl. B81B 7/00; B06B 1/02; B81C 1/00

(52) U.S. Cl. CPC B81B 7/007; B06B 1/0292; B81B 7/0093; B81C 1/00301; B06B 2201/76; B81B 2207/096; B81B 2207/097; B81C 2203/0127; B81B 2201/0271

(57) ABSTRACT

A method of forming a multiple layer, hybrid interposer structure includes forming a plurality of first openings through a substrate, the substrate comprising a heat spreading material; forming a first metal material within the plurality of first openings and on top and bottom surfaces of the substrate; patterning the first metal material; forming a dielectric layer over the patterned first metal material; forming a plurality of second openings within the dielectric layer to expose portions of the patterned first metal material on the top and bottom surfaces of the substrate; filling the plurality of second openings with a second metal material, in contact with the exposed portions of the patterned first metal material; forming a third metal material on the top and bottom surfaces of the substrate, the third metal material in contact with the second metal material and the dielectric layer; and patterning the third metal material.

### CROSS-REFERENCE TO RELATED APPLICATIONS

This application claims the benefit under 35 U.S.C. § 119(e) of U.S. Patent Application Ser. No. 62/798,446, filed Jan. 29, 2019 under Attorney Docket No. B1348.70130US00, and entitled “PACKAGING STRUCTURES AND PACKAGING METHODS FOR ULTRASOUND-ON-CHIP DEVICES,” which is hereby incorporated herein by reference in its entirety.

### BACKGROUND

The present disclosure relates generally to ultrasound systems and, more specifically, to packaging structures and packaging methods for ultrasound-on-chip devices.

Ultrasound devices may be used to perform diagnostic imaging and/or treatment, using sound waves with frequencies that are higher than those audible to humans. When pulses of ultrasound are transmitted into tissue, sound waves are reflected off the tissue with different tissues reflecting varying degrees of sound. These reflected sound waves may then be recorded and displayed as an ultrasound image to the operator. The strength (amplitude) of the sound signal and the time it takes for the wave to travel through the body provide information used to produce the ultrasound images.

Some ultrasound imaging devices may be fabricated using micromachined ultrasonic transducers, including a flexible membrane suspended above a substrate. A cavity is located between part of the substrate and the membrane, such that the combination of the substrate, cavity and membrane form a variable capacitor. When actuated by an appropriate electrical signal, the membrane generates an ultrasound signal by vibration. In response to receiving an ultrasound signal, the membrane is caused to vibrate and, as a result, generates an output electrical signal.

### SUMMARY

In one aspect, a method of forming a multiple layer, hybrid interposer structure includes forming a plurality of first openings through a substrate, the substrate comprising a heat spreading material; forming a first metal material within the plurality of first openings and on top and bottom surfaces of the substrate; patterning the first metal material; forming a dielectric layer over the patterned first metal material; forming a plurality of second openings within the dielectric layer to expose portions of the patterned first metal material on the top and bottom surfaces of the substrate; filling the plurality of second openings with a second metal material, in contact with the exposed portions of the patterned first metal material; forming a third metal material on the top and bottom surfaces of the substrate, the third metal material in contact with the second metal material and the dielectric layer; and patterning the third metal material.

In another aspect, a method of forming a packaging structure for an ultrasonic transducer device includes attaching a multiple layer, flex substrate to a carrier wafer; bonding a first side of an ultrasound-on-chip device to the flex substrate; bonding a second side of the ultrasound-on-chip device to a first side of a hybrid substrate that provides both heat spreading and signal distribution; and removing the carrier wafer.

### BRIEF DESCRIPTION OF THE DRAWINGS

Various aspects and embodiments of the application will be described with reference to the following figures. It should be appreciated that the figures are not necessarily drawn to scale. Items appearing in multiple figures are indicated by the same reference number in all the figures in which they appear.

FIG. 1 is a flow diagram describing an exemplary process flow for forming a hybrid interposer structure that includes both heat spreading and signal distribution capabilities, according to an embodiment.

FIGS. 2-1 through 2-12 are a series of cross-sectional views illustrating the exemplary process flow of FIG. 1.

FIG. 3 is a cross-sectional view of a completed hybrid interposer structure according to an embodiment.

FIG. 4 is a cross-sectional view of a completed hybrid interposer structure according to another embodiment.

FIG. 5 is a cross-sectional view illustrating an exemplary pre-packaged ultrasound-on-chip assembly that may be bonded to the hybrid interposer structure of FIG. 3.

FIG. 6 is a cross-sectional view illustrating bonding of the pre-packaged ultrasound-on-chip assembly to the hybrid interposer structure of FIG. 3.

FIG. 7 is a cross-sectional view illustrating an alternative embodiment of the structure of FIG. 6, in which the ultrasound-on-chip packaging is implemented on the hybrid interposer structure of FIG. 3.

FIG. 8 is a flow diagram describing an exemplary process flow for packaging an ultrasound-on-chip device, according to an embodiment.

FIGS. 9-1 through 9-6 are a series of cross-sectional views illustrating the exemplary process flow of FIG. 8.

FIG. 10 is an alternative embodiment of the structure shown in FIG. 9-6.

### DETAILED DESCRIPTION

The techniques described herein relate to packaging structures and packaging methods for ultrasound-on-chip devices.

One type of transducer suitable for use in ultrasound imaging devices is a micromachined ultrasonic transducer (MUT), which can be fabricated from, for example, silicon and configured to transmit and receive ultrasound energy. MUTs may include capacitive micromachined ultrasonic transducers (CMUTs) and piezoelectric micromachined ultrasonic transducers (PMUTs), both of which can offer several advantages over more conventional transducer designs such as, for example, lower manufacturing costs and fabrication times and/or increased frequency bandwidth. With respect to the CMUT device, the basic structure is a parallel plate capacitor with a rigid bottom electrode and a top electrode residing on or within a flexible membrane. Thus, a cavity is defined between the bottom and top electrodes. In some designs (such as those produced by the assignee of the present application for example), a CMUT may be directly integrated on an integrated circuit that controls the operation of the transducer. One way of manufacturing a CMUT is to bond a membrane substrate to an integrated circuit substrate (e.g., such a complementary metal oxide semiconductor (CMOS) substrate), at temperatures sufficiently low to prevent damage to the devices of the integrated circuit, thus defining an ultrasound-on-chip device.

In a portable ultrasound imaging device, (such as those produced by the assignee of the present application for example), an ultrasound-on-chip device may be packaged in a manner so as to provide heat dissipation from surfaces of the integrated circuit, as well as to provide one or more electrical signal paths between the ultrasound-on-chip device and other components of the portable ultrasound imaging device (e.g., field programmable gate arrays (FPGAs), memory devices, and various other electronic components, etc.). To this end, one possible packaging arrangement may include an acoustic backing material (e.g., tungsten containing epoxy) disposed between the CMOS substrate and a metallic heat sink material (e.g., copper). An opposing side of the heat sink material may in turn be disposed on a printed circuit board (PCB) interposer. Electrical connection between the ultrasound-on-chip device and the PCB interposer may be facilitated through the use of individual wirebonds, a height of which may depend on a combined thickness of the individual ultrasound-on-chip, acoustic backing, and heat sink structures.

In some instances, a large number of such wirebonds having a relatively long bonding length due to this height may result in undesired parasitic inductance and resistance, which in turn can result in lower power efficiency and increased heating. Moreover, the use of a metallic material, such as copper, for a heat sinking device can result in a mismatch of the coefficient of thermal expansion (CTE) between the metal and the substrate material (e.g., silicon) of the CMOS. Accordingly, the inventors have recognized that certain alternative interposer/heat spreading materials may be helpful for bonding to the ultrasound-on-a-chip. Furthermore, such interposers may have a “hybrid” functionality by providing both heat spreading and signal routing functions, with the added benefit of better CTE matching to the CMOS substrate.

One example of such an alternative interposer structure is a ceramic substrate, such as for example aluminum nitride (AlN), that is further configured with though-via electrical conductors by, for example, using a direct plated copper (DPC) process that combines thin film and electrolytic plating processes. Here, the ceramic AlN material functions as a heat spreading material that better matches the CTE of silicon as compared to a metal heat sinking material such a copper. The interposer may lack sufficient mass to function as a heat sink, but rather may function as a heat spreader, distributing heat away from an ultrasound-on-chip device. In at least some embodiments, the interposer may exhibit sufficient stiffness to serve as a support for the ultrasound-on-chip device. In addition, this “hybrid” AlN interposer can directly communicate electrical signals between the ultrasound-on-chip device and the PCB interposer. Thus, where wirebonds are used to connect to the ultrasound-on-chip device, such wirebonds may be made shorter than those described above since the wirebonds need only extend from the ultrasound-on-chip device to the top of the AlN interposer, instead of all the way down to the top of the PCB. Alternatively, other connection structures may be utilized for electrically connecting the ultrasound-on-chip device to the hybrid AlN interposer, such as through-silicon vias (TSVs) formed in the ultrasound-on-a-chip.

As described, various aspects provide a hybrid interposer for connection to an ultrasound sensor chip or ultrasound-on-a-chip device. The hybrid interposer may possess a CTE substantially the same as that of silicon, which may be the material of a substrate of the ultrasound-on-chip-device. For example, the CTE of silicon is approximately 2.6 ppm/K. The CTE of the interposer material may be less than 5 ppm/K in at least some embodiments, including any value between 5 ppm/K and 2.5 ppm/K, as non-limiting examples. In some embodiments, the hybrid interposer has a CTE of approximately 4.5 ppm/K. The hybrid interposer may possess a stiffness sufficient to function as a support for the ultrasound-on-chip device and in at least some embodiments may be substantially rigid. Such structural stiffness may be particularly beneficial when the ultrasound-on-chip device is relatively thin and has a large surface area, such as being tens of microns thick, as a non-limiting example. In some embodiments, the thermal conductivity of the interposer may be between 150 W/m/K and 200 W/m/K, for example being approximately 170 W/m/K. Such thermal conductivities may facilitate the heat spreading function of the hybrid interposer. However, the hybrid interposer may lack sufficient mass to function as a heat sink maintaining the temperature of the device below some target temperature. Thus, in some embodiments, the hybrid interposer may be thermally coupled to a heat sink. Non-limiting examples of suitable hybrid interposer materials include AlN and SiN. The hybrid interposer may be thermally connected to a heat sink.

Additional information regarding hybrid ceramic interposers and TSV structures for ultrasound-on-a-chip devices may be found in application 62/623,948 (the '948 application), assigned to the assignee of the present application, the contents of which are incorporated herein in their entirety. Additional information regarding hybrid ceramic interposers and TSV structures for ultrasound-on-a-chip devices may also be found in co-pending application Ser. No. 16/260,242 (the '242 application), assigned to the assignee of the present application, and published as U.S. Pat. Pub. 2019/0231312 A1, the contents of which are incorporated herein in their entirety.

The inventors have recognized that it may be further advantageous to combine the functions of both a hybrid ceramic interposer and a PCB into a single integrated substrate, which is also subsequently referred to herein as a multilayer DPC or MLDPC substrate. As will also be described herein, the MLDPC substrate may be used as part of one or more packaging structure embodiments for an ultrasound-on-chip device.

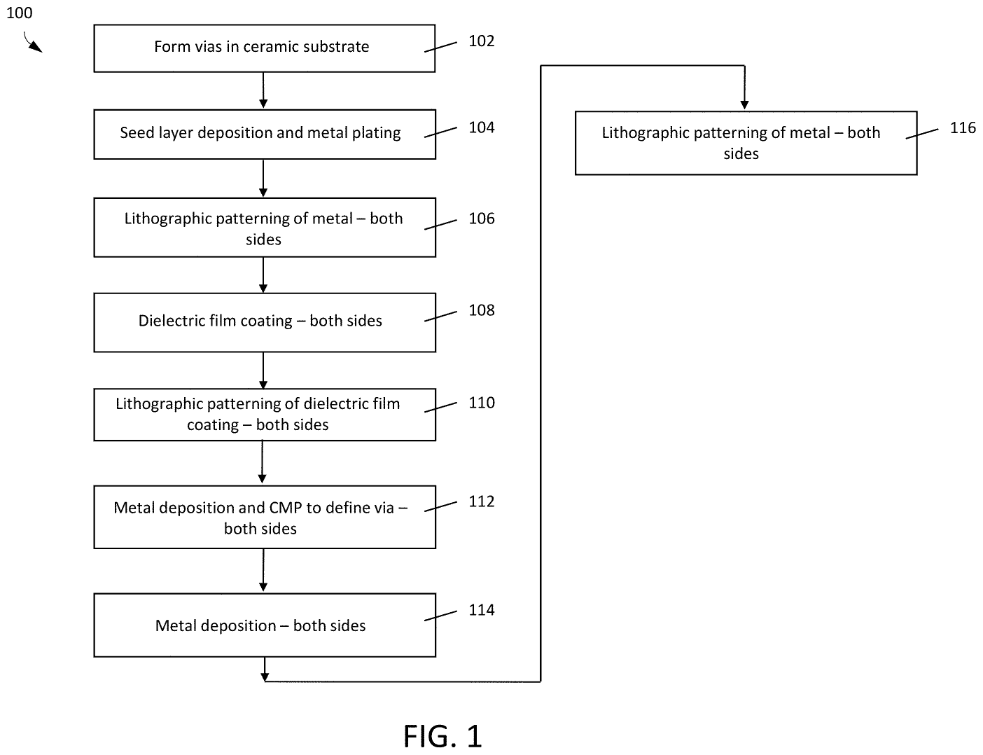

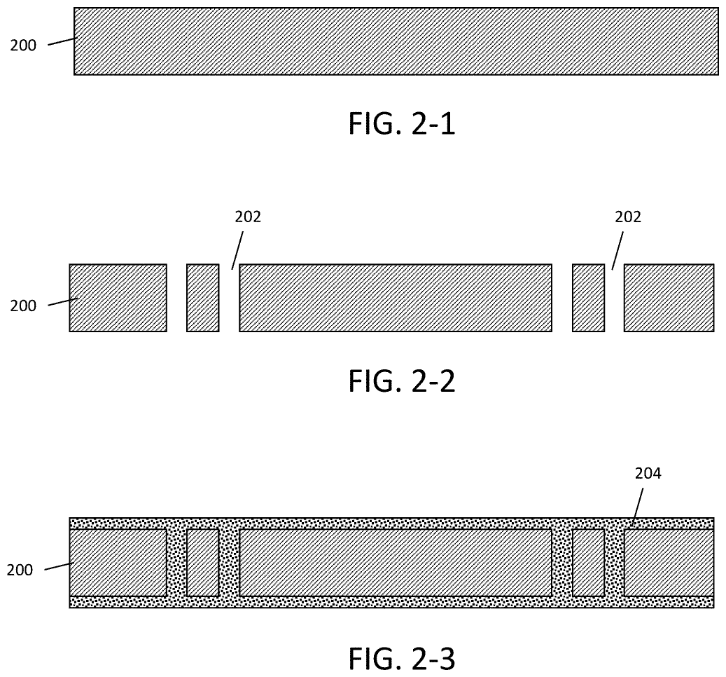

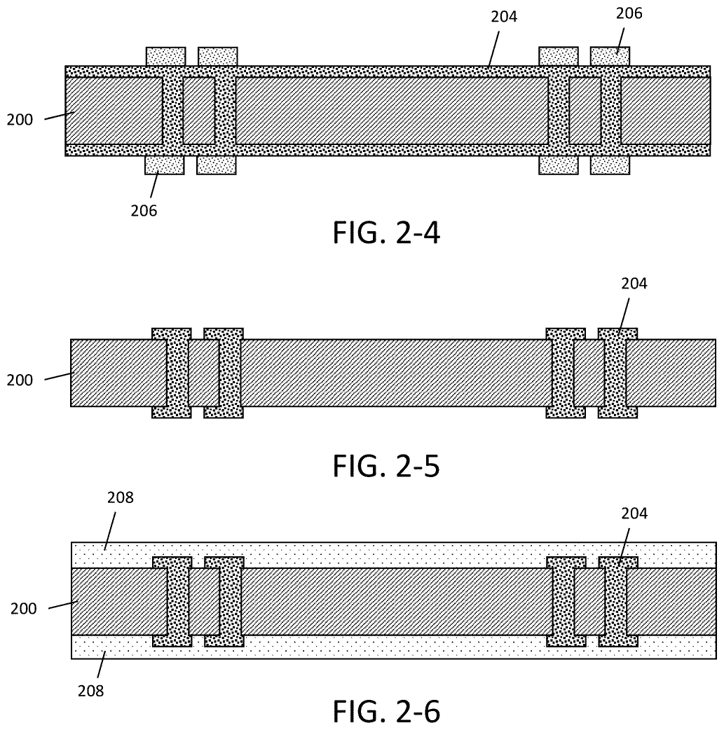

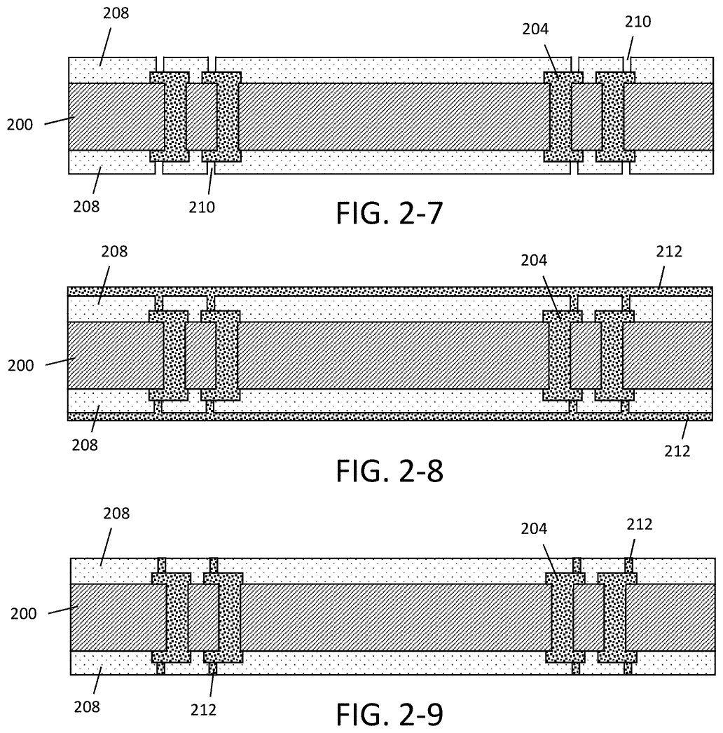

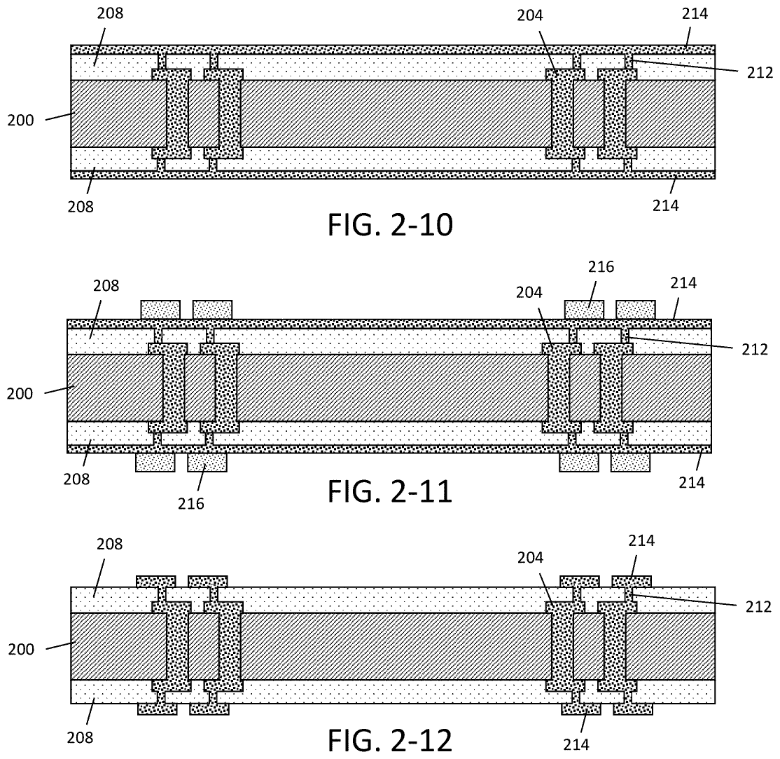

Referring generally now to FIG. 1 and FIGS. 2-1 through 2-12, there is respectively shown a flow diagram and a series of cross-sectional views illustrating a process flow 100 for forming a hybrid interposer structure that provides both heat spreading and signal distribution functions, according to an embodiment. The process flow 100 commences at block 102 of FIG. 1 by forming vias in a ceramic substrate. The ceramic substrate 200, illustrated in FIG. 2-1, may be a material such as AlN for example, although other suitable CTE matching materials with respect to silicon or other III-V based semiconductor materials are also contemplated, including but not limited to: aluminum oxide (Al₂O₃), zirconium toughened aluminum (ZTA), silicon nitride, and beryllium oxide (BeO). Openings 202, shown in FIG. 2-2, may be formed completely through a thickness of the substrate 200 by laser drilling for example.

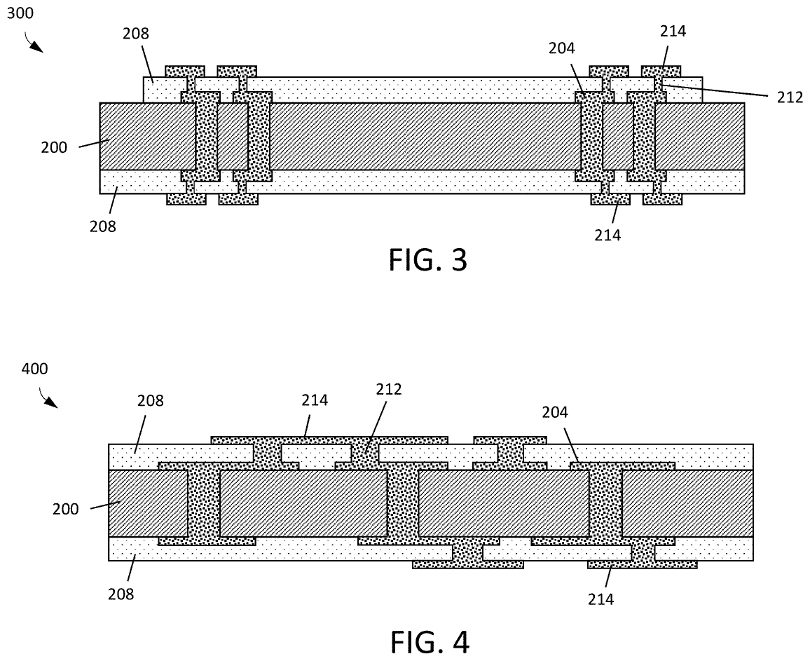

As indicated in block 104 of FIG. 1, the process flow 100 continues with seed layer deposition and metal plating. For ease of illustration, FIG. 2-3 depicts a single (first) metal material 204 disposed within the openings 202 of FIG. 2-2 as well as on top and bottom surfaces of the substrate 200. It should be understood, however, that the first metal material 204 may represent the combination of a sputtered thin metal seed layer followed by plated copper (Cu). Then, as indicated in block 106 of FIG. 1, the process flow 100 continues with lithographic patterning and etching of the first metal material 204 on both sides of the substrate 200. The lithographic patterning is illustrated by the patterned photoresist material 206 shown in FIG. 2-4 and etching of the exposed metal material shown in FIG. 2-5; however, it should be appreciated that this sequence does not necessarily represent the specific order in which resist patterning and metal etching is performed. In other words, one side of the first metal material 204 may be patterned and etched, followed by repeating on the opposite side. Following etching of the first metal material 204 (using the ceramic substrate 200 as an etch stop layer for example) removal of the remaining resist material 206 results in the structure of FIG. 2-5. It should be noted that the specific metal pattern depicted in FIG. 2-5 is just one example of a pattern, and that other metal patterns having different shapes, asymmetric features, etc. are also contemplated within the scope of the present disclosure.

Proceeding now to block 108 of FIG. 1, the process flow 100 continues with the formation of a dielectric film coating (layer) 208 on both sides of the structure of FIG. 2-5, which results in the structure shown in FIG. 2-6. The dielectric film 208 may be SiO₂, for example, or any suitable electrically insulating material. Then, as indicated in block 110 of FIG. 1 and illustrated in FIG. 2-7 openings 210 are formed in the dielectric film 208, on both sides of the substrate 200 so as to expose a portion of the first metal material 204. As indicated in block 112 of FIG. 1, openings 210 are then filled by deposition and subsequent planarization (e.g., by chemical mechanical polishing (CMP)) of a second metal material 212 (e.g., copper). FIG. 2-8 illustrates deposition of the second metal material 212 and FIG. 2-9 illustrates the resulting structure after CMP of the second metal material 212 to the top surfaces of the dielectric film 208. Thus, remaining portions of the second metal material 212 in FIG. 2-9 define vias that electrically connect to the first metal material 204.

Referring again to FIG. 1, the process 100 continues at block 114 with a deposition of a third metal material 214, as illustrated in FIG. 2-10. The third metal material 214 may be the same metal material as the first and second metal (e.g., copper). The sequence illustrated in FIGS. 2-8, 2-9, and 2-10 may facilitate formation of a metal layer of desired thickness. The result of FIG. 2-8 may be a metal layer of uneven thickness, and thus the steps shown in FIGS. 2-9 and 2-10 may facilitate achieving a more uniform thickness of a desired value. This is followed by lithographic patterning and etching of the third metal material 214 (on both sides of the substrate 200) as indicated at block 116 of FIG. 1 and illustrated in FIG. 2-11 and FIG. 2-12. The lithographic patterning is illustrated by the patterned photoresist material 216 shown in FIG. 2-11, and etching of the exposed metal material is shown in FIG. 2-12. Similar to the patterning of the first metal material 204, however, it should be appreciated that the sequence of FIG. 2-11 and FIG. 2-12 does not necessarily represent the specific order in which resist patterning and metal etching may be performed. In other words, one side of the first metal material 214 may be patterned and etched, followed by repeating on the opposite side.

Depending on a desired application for a hybrid interposer structure, one or more additional processing operations may also be performed, such as patterning the dielectric layer 208 on one or both sides of the substrate 200 to configure a particular geometry. For example, FIG. 3 illustrates one possible embodiment of a completed multilayer direct plated copper (MLDPC) hybrid interposer structure 300. The configuration illustrated in FIG. 3 includes exposed side surfaces of the dielectric film 208. The dielectric film 208 may be etched to provide the exposed side surfaces or edges. A metal shroud may then be placed in contact with the exposed side surfaces, forming a pathway for dissipation of heat away from the device.

As indicated above, however, it is contemplated that other metal layer patterns may be used depending on the desired heat spreading and signal redistribution capabilities of the structure. By way of an additional example, FIG. 4 illustrates another possible embodiment of a completed MLDPC hybrid interposer structure 400, which structure may have different metal thicknesses, dielectric thicknesses, metal connection patterns, etc. than the structure 300 of FIG. 3. In both the embodiment of FIG. 3 and FIG. 4, the MLDPC structures may be considered to be 4-level DPC structures, in that on each side of the substrate, there are two distinct metal interconnection levels. It will readily be appreciated, however, that a different number (more or less) of metal levels may be fabricated, whether on one side, the opposite side or both sides of the substrate 200.

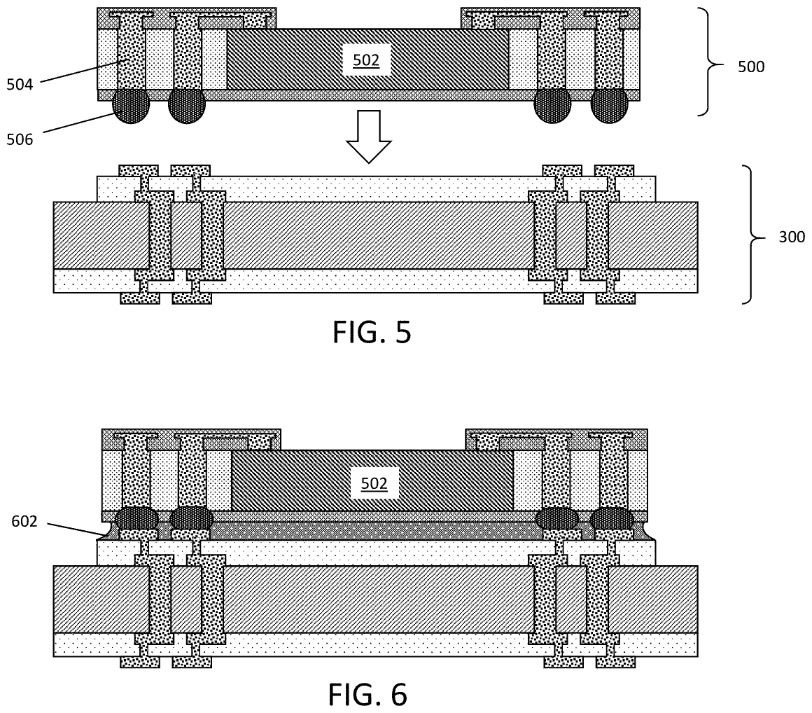

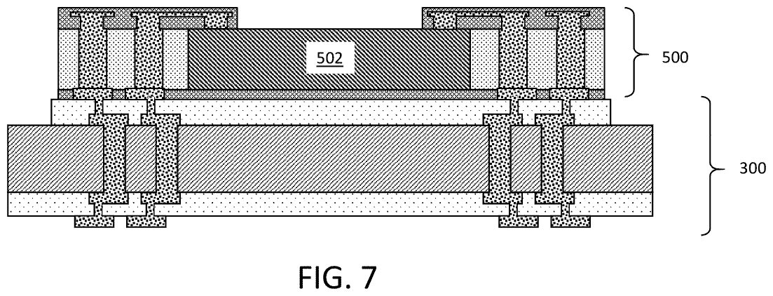

Turning now to FIG. 5 and FIG. 6, an exemplary use for an MLDPC hybrid interposer structure, such as the structure 300 of FIG. 3, is illustrated. More specifically, FIG. 5 illustrates an exemplary pre-packaged ultrasound-on-chip assembly 500 that may be bonded to the hybrid interposer structure of FIG. 3. In the example depicted, an ultrasound-on-chip 502 is pre-packaged in accordance with an integrated fan-out (InFO) packaging process, which includes forming copper pillars 504 as part of a signal redistribution structure for individually diced and molded chips, and using solder ball connections 506. FIG. 6 illustrates the bonded InFO packaged ultrasound-on-chip assembly 500 to the MLDPC hybrid interposer structure 300 using, for example, an epoxy type underfill material 602. Such a scheme may be referred to as an “InFO first” process, in that the ultrasound-on-chip 502 is packaged by InFO prior to bonding with the MLDPC hybrid interposer structure 300. Alternatively, FIG. 7 illustrates an alternative embodiment of the structure of FIG. 6, in which an “InFO last” process is used to perform the ultrasound-on-chip packaging is implemented on the hybrid interposer structure 300.

As indicated above, other ultrasound-on-chip packaging approaches may be used as an alternative to InFO packaging, either alone or in combination with interposer substrates. Referring now to FIG. 8 and FIGS. 9-1 through 9-6, there is respectively shown a flow diagram and a series of cross-sectional views illustrating a process flow 800 for an exemplary process flow for packaging an ultrasound-on-chip device, according to an embodiment. It will be noted that like reference numbers may be used to designate similar elements in the various embodiments. Such an exemplary process provides packaging and signal redistribution for an ultrasound-on-chip device, and in addition may eliminate the need for more complicated and expensive processes, such as copper pillar electroplating and molding.

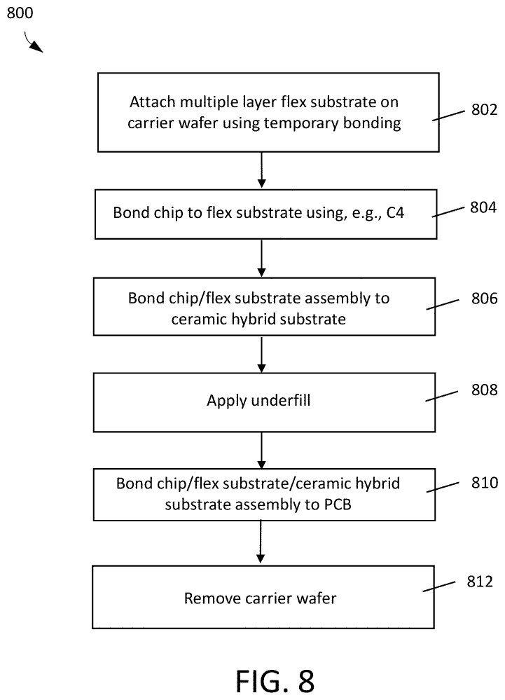

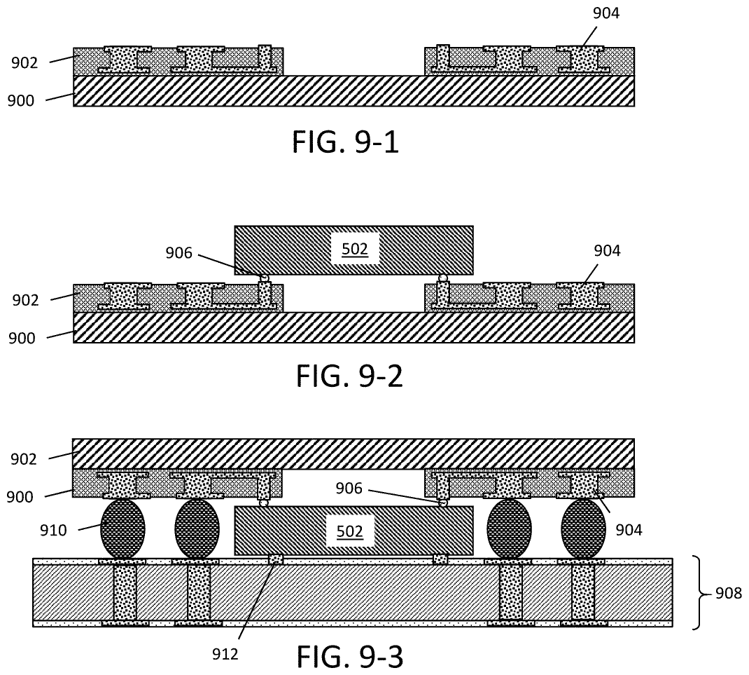

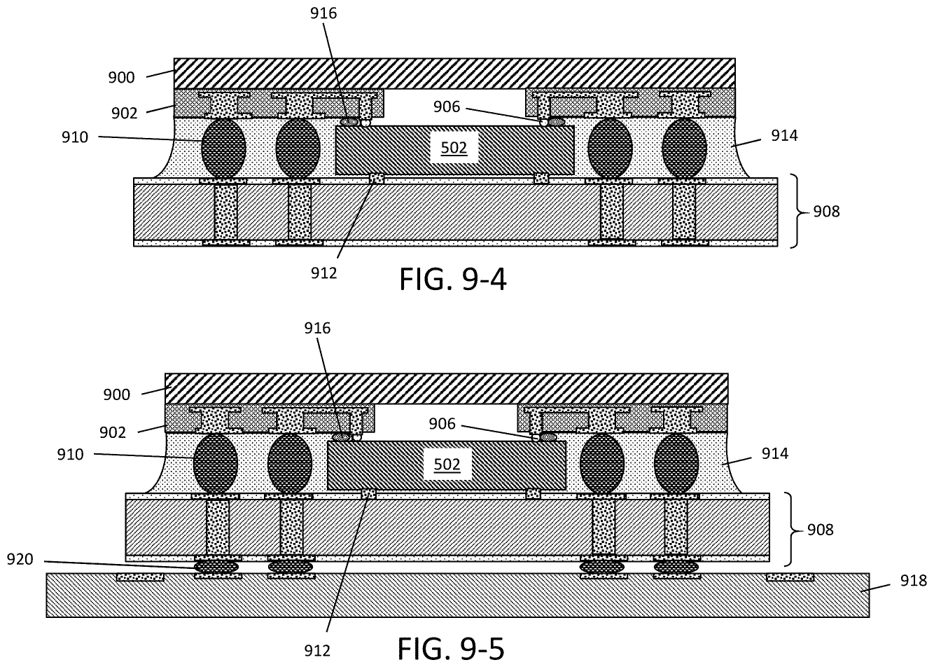

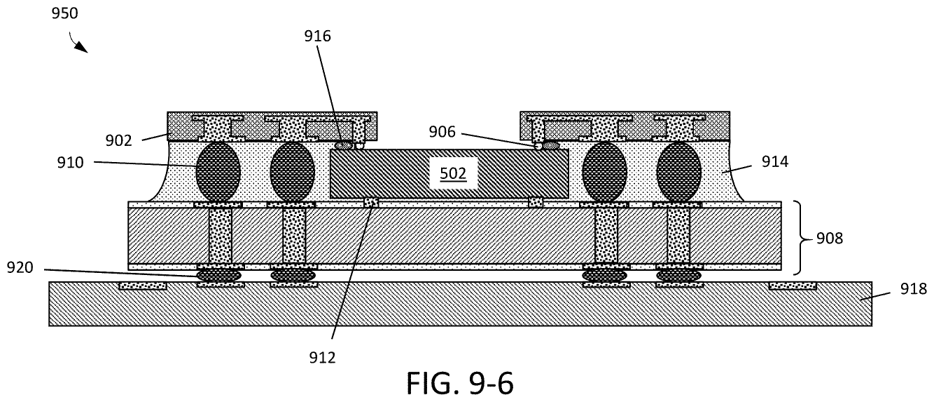

The process flow 800 commences at block 802 of FIG. 8 by attaching a multiple layer flex substrate on a carrier wafer using temporary bonding. The carrier wafer 900, illustrated in FIG. 9-1, may be a material such as silicon for example, although other suitable carrier materials are also contemplated. A multiple layer flex circuit substrate 902, also shown in FIG. 9-1, is temporarily bonded to the carrier wafer 900. The multiple layer flex circuit substrate 902 (e.g., formed from materials such as copper clad polyimide, PTFE, or organic laminates) may have one or more levels of plated through holes 904 formed therein. As indicated in block 804 of FIG. 8 and shown in FIG. 9-2, an ultrasound-on-chip device 504 is bonded to the flex substrate 902 using, for example flip-chip (C4) technology including solder balls 906.

The resulting chip/flex substrate assembly may then be bonded to a ceramic hybrid substrate 908 (e.g., AlN DPC) as indicated in block 806 of FIG. 8 and shown in FIG. 9-3. In an exemplary embodiment, the chip/flex substrate assembly bonds to the AlN DPC substrate 908 may be controlled by the dimensions of solder balls 910. The gap between the chip 502 and the AlN DPC substrate 908 may be further controlled by plated Cu pads 912 formed on the AlN DPC substrate 908.

Referring again to FIG. 8, the process 800 continues at block 808 with the application of an underfill material 914, such as an epoxy based material illustrated in FIG. 9-4. A gasket material 916, such as an epoxy, may be disposed between the flex circuit substrate 902 and the chip 502 to limit the flow of the underfill material 914. Then, as indicated in block 810 of FIG. 8 and illustrated in FIG. 9-5, the chip/flex substrate/AlN DPC substrate assembly of FIG. 9-4 is bonded to a PCB 918 by, for example, surface mount technology (SMT) featuring solder connections 920. Once the PCB bonding is completed, the carrier wafer 900 may then be removed to define a packaged ultrasound-on-chip device 950 as indicated in block 812 of FIG. 8 and illustrated in FIG. 9-6.

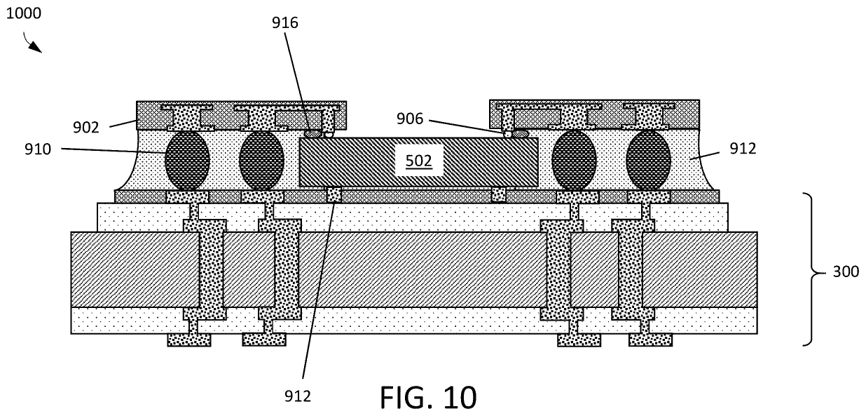

It will readily be appreciated that, in addition to the embodiments described above (e.g., an InFO chip mounted on the MLDPC substrate, and a flex-packaged chip mounted on a DPC interposer/PCB assembly), a combination of the two approaches is also possible. For instance, the MLDPC fabrication approach illustrated in FIG. 1 and FIGS. 2-1 through 2-12 may be used in conjunction with the flex substrate chip packaging approach illustrated in FIG. 8 and FIGS. 9-1 through 9-6. As illustrated in FIG. 10, a packaged ultrasound-on-chip device 1000 includes a flex substrate packaged chip mounted on an MLDPC substrate 300 that provides both heat spreading and signal distribution functionality.

The above-described embodiments can be implemented in any of numerous ways. For example, the embodiments may be implemented using hardware, software or a combination thereof. When implemented in software, the software code can be executed on any suitable processor (e.g., a microprocessor) or collection of processors, whether provided in a single computing device or distributed among multiple computing devices. It should be appreciated that any component or collection of components that perform the functions described above can be generically considered as one or more controllers that control the above-discussed functions. The one or more controllers can be implemented in numerous ways, such as with dedicated hardware, or with general purpose hardware (e.g., one or more processors) that is programmed using microcode or software to perform the functions recited above.

Various aspects of the present invention may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, some aspects of the technology may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

What is claimed is:

1. A method of forming a multiple layer, hybrid interposer structure, the method comprising:
forming a plurality of first openings through a substrate, the substrate comprising a heat spreading material;
forming a first metal material within the plurality of first openings and on top and bottom surfaces of the substrate;
patterning the first metal material on the top and bottom surfaces of the substrate;
forming a dielectric layer over the patterned first metal material on the top and bottom surfaces of the substrate;
forming a plurality of second openings within the dielectric layer to expose portions of the patterned first metal material on the top and bottom surfaces of the substrate;
filling the plurality of second openings with a second metal material, in contact with the exposed portions of the patterned first metal material;
forming a third metal material on the top and bottom surfaces of the substrate, the third metal material in contact with the second metal material and the dielectric layer; and
patterning the third metal material.

2. The method of claim 1, wherein the substrate comprises a ceramic material.

3. The method of claim 2, wherein the ceramic material comprises aluminum nitride (AlN).

4. The method of claim 1, wherein filling the plurality of second openings with the second metal material comprises:
depositing the second metal material in the plurality of second openings and over the dielectric layer; and
performing chemical mechanical planarization (CMP) of the second metal material down to the dielectric layer.

5. A method of forming a packaging structure for an ultrasonic transducer device, the method comprising:
attaching a multiple layer, flex substrate to a carrier wafer;
bonding a first side of an ultrasound-on-chip device to the flex substrate;
bonding a second side of the ultrasound-on-chip device to a first side of a hybrid substrate that provides both heat spreading and signal distribution; and
removing the carrier wafer.

6. The method of claim 5, further comprising applying an underfill material around the ultrasound-on-chip device, between the multiple layer, flex substrate and the hybrid substrate.

7. The method of claim 5, wherein the hybrid substrate comprises a ceramic material having vias formed therein.

8. The method of claim 7, further comprising bonding a second side of the hybrid substrate to a printed circuit board (PCB).
